(19) United States
(12) Patent Application Publication
(10) Pub. No.: US 2023/0262904 A1
(43) Pub. Date: Aug. 17, 2023

(54) METHOD FOR AT LEAST PARTIALLY CLOSING A CHANNEL-SHAPED OPENING

(71) Applicant: Peters Research GmbH & Co. Kommanditgesellschaft, Kempen (DE)

(72) Inventors: Ralf SCHWARTZ, Krefeld (DE); Michael MÜLLER, Oberhausen (DE); Johannes TEKATH, Coesfeld (DE)

(21) Appl. No.: 18/012,103

(22) PCT Filed: Jul. 1, 2021
(86) PCT No.: PCT/EP2021/068241

§ 371 Date: Dec. 21, 2022

(30) Foreign Application Priority Data
Jul. 3, 2020 (EP) 20184034.5

(51) Int. Cl. H05K 3/00

(52) U.S. Cl. CPC H05K 3/0094; H05K 2203/013; H05K 2203/0763; H05K 2203/1572; H05K 2201/0959

(57) ABSTRACT

A method for closing a channel-shaped opening with a cross-sectional area and a passage length, more particularly through-bores or plated through-holes in printed circuit boards, using a liquid curable or curing filler material. The opening is closed by a digitally controlled application method with two discharge heads arranged opposite one another, preferably in an inkjet method with two discharge heads designed as print heads and arranged opposite one another. The two discharge heads are controlled such that the opening is filled with the filler material from both sides through the two ends simultaneously. The filler material is discharged by the two discharge heads such that the quantities of discharged filler material meet inside the opening.

The invention relates to a method for at least partially closing a channel-shaped opening with a cross sectional surface area and a passage length, in particular through-holes or through-platings in printed-circuit boards, with a liquid, curable or curing filling material.

In practice, extremely different methods are known in order to close channel-shaped openings. However, many methods cannot be used in all technical fields or their use involves disadvantages in many sectors.

Thus, for example, closing through-holes or through-platings in printed-circuit boards is connected with particular requirements. This is because, during the production of printed-circuit boards, there are used extremely varied coatings which may comprise etch resists for structuring the conductive pattern, solder resists, printed identifications, via hole fillers and other functional coating layers. These coatings are generally applied selectively and using a screen printing method. In the case of solder resists, photolithographic processes are also used because finer structures can thereby be constituted.

Since, for screen printing, a stencil corresponding to the print layout has to be used and corresponding exposure films are necessary for the photolithographic structurable coatings, deviations such as, for example, layout changes, or small batches are correspondingly time-consuming and expensive. Alternatively, the exposure can also be carried out directly by means of laser structuring. After the exposure, a development process, by which the non-exposed coating areas are removed by means of corresponding developer media, is then necessary.

However, the desired coatings can also be selectively applied directly by means of digitally controlled application processes, whereby many process steps and consequently both time and material can be saved. These processes are therefore intended for small batches up to batch sizes of 1 and simple layout changes.

In practice, some of the production processes are already carried out with digitally controlled application processes, wherein inkjet printing is a particularly preferred coating method.

In the case of printed-circuit boards with more complex structures, often more than one plane with conductive structures is provided. In this case, these so-called multi-layers require conductive connections between the individual planes which are conventionally produced by through-platings. These through-platings are through-holes or holes which are formed in the printed-circuit board, wherein the electrically conductive contact is produced, for example, by metal-coating the borehole wall.

In practice, however, there may be a need to close the through-holes again subsequently. This may, for example, be as a result of so-called in-circuit tests, wherein the printed-circuit board is tested with regard to its electrical function and to this end has to be fixed on a specific carrier by vacuum adaptation. However, this is not possible if through-holes prevent a vacuum from being able to act over the entire printed-circuit board surface-area.

After the fitting thereof, it may further be necessary to provide the printed-circuit board with components with an additional protective coating. However, these protective coatings which are generally of low viscosity can flow away through the through-holes onto the opposite side of the printed-circuit board and, on the one hand, are consequently absent at the coating side and can also flow into regions which are not intended to be or even must not be coated.

Furthermore, chemicals from wet-chemical processes which are used to upgrade the copper surfaces can accumulate in unfilled through-holes, that is, in through-holes which are (still) open, and can remain there and subsequently lead to corrosion effects at this location, and consequently, for example, weaken or even destroy the through-plating.

Furthermore, it may be necessary or at least advantageous to fill the through-holes functionally with a correspondingly formed filling material. This may be a complete filling with electrically and/or thermally conductive, magnetizable, dielectric or particularly low-expansion materials.

An object of the invention is to prevent the above-mentioned disadvantages and to provide methods for at least partially closing a channel-shaped opening with a cross sectional surface-area and a passage length, with which the partial closure of the channel-shaped opening is readily possible.

This object is achieved in a generic method in that the closure of the opening is carried out by means of a digitally controlled application method with two discharge heads which are arranged opposite each other, preferably with an ink jet method with two discharge heads which are arranged opposite each other and which are in the form of print heads, wherein the two discharge heads are controlled in such a manner that the opening is filled with the filling material from both sides by the two ends at the same time and the filling material is discharged from the two discharge heads taking into consideration the respective performance data of the two discharge heads and the respective spacing of the two discharge heads from the opening so that the discharged quantities of the filling material meet each other inside the opening.

Advantageously, the cross sectional surface-area of the opening may not have in any direction an extent which is greater than 8 mm, preferably no greater than from 3 mm to 5 mm. The cross sectional surface-area of the opening may be circular, which is the case, for example, with bores.

Consequently, the filling material which is injected by the discharge heads into the opening does not flow through the opening, but instead meets the filling material which is coming from the other direction, whereby the filling material sprays away to the side and accumulates against the wall of the opening.

In this case, the filling material can be discharged at a speed of from 5 m/s to 10 m/s from the discharge heads. This can be carried out, for example, intermittently so that drops are discharged. The volume of the drops may be, for example, from 1 pl (picolitre) to 20 pl, preferably from 3 pl to 10 pl. In this case, the frequency of the drop discharge may be from 5 kHz to 10 kHz. During intermittent discharge of the filling material, for example, the curing may also be carried out intermittently in the time ranges if no discharge of the filling material is carried out. Such timed curing can be carried out with a suitable filling material, for example, by means of a stroboscope.

In this case, the two discharge heads can be controlled according to the invention in such a manner that the filling material is discharged from the two discharge heads taking into consideration the respective performance data of the two discharge heads and the respective spacing of the two discharge heads from the opening so that the discharged quantities of the filling material meet each other at least approximately in the region of the center of the passage length of the opening. This is particularly advantageous in the case of complete filling because initially a dividing wall which is arranged at the center of the passage length of the opening is then formed and the two blind holes which thereby result can then be further filled by the associated discharge head.

Alternatively, the discharge of the filling material can also be carried out by the discharge heads in such a manner that the discharged quantities of the filling material meet each other approximately in the region of one end of the opening. Consequently, the opening can be closed at one side at least approximately in a flush manner, whereas it can remain open from the other side and can remain unfilled.

The two discharge heads can also be controlled in such a manner that the filling material is discharged from the two discharge heads taking into consideration the respective performance data of the two discharge heads and the respective spacing of the two discharge heads from the opening so that the discharged quantities of the filling material meet each other at least approximately in the region of the center of the cross sectional surface-area of the opening so that the introduced material then sprays uniformly against the wall of the opening with suitable dimensions of the cross sectional surface-area of the opening.

Alternatively, the discharge of the filling material can also be carried out by the discharge heads in such a manner that the discharged quantities of the filling material meet approximately in the region of the wall of the opening. Consequently, the opening can be at least partially closed starting from a wall region if, for example, the cross sectional surface-area is too great for the opening to be able to be closed in one step.

Preferably, the two discharge heads can be controlled in such a manner that the filling material is discharged from the two discharge heads taking into consideration the respective performance data of the two discharge heads and the respective spacing of the two discharge heads from the opening so that the cross sectional surface-area of the opening is completely closed. As a result, passage through the opening is then blocked.

According to the invention the two discharge heads can also be controlled in such a manner that the filling material is discharged from the two discharge heads taking into consideration the respective performance data of the two discharge heads and the respective spacing of the two discharge heads from the opening so that the opening is completely closed. Consequently, the opening is closed at both sides at least approximately in a flush manner. No cavity in which undesirable accumulations of residues of other materials can form remains.

Advantageously, the filling material may be a melt adhesive which is also referred to as a “hot melt”. Consequently, curing already results simply as a result of the cooling, which can also be accelerated by an air flow or the like.

The filling material may also be a UV-curable and/or electron-beam-curable and/or thermally curable ink so that the curing operation can be selectively controlled.

The filling material can be free from solvents or contain at least one solvent according to the invention.

The filling material can also be free from particles or filled with particles. In this case, at least some particles, preferably all the particles, may be in the nano-scale size range. At least some particles, preferably all the particles, may also be thermally conductive.

Furthermore, at least some particles, preferably all the particles, may be electrically conductive or dielectric. Consequently, for example, the filling of the opening in a printed-circuit board may either act as a through-plating or an electrical connection of the planes of the printed-circuit board can be prevented by the opening being filled.

At least some particles, preferably all the particles, may also be magnetic.

According to the invention the two discharge heads can be orientated in such a manner that the trajectory of the filling material which is discharged therefrom is orientated vertically or is redirected only slightly from the perpendicular or is orientated horizontally or is redirected only slightly from the horizontal.

For complete filling, the drops can ideally meet at the center of the cross sectional surface-area of the opening and then atomize sideways and wet the wall of the opening. If the cross sectional surface-area is closed, the opening is then further filled from the inner side.

In the case of a horizontal orientation, the drops sink at the flight end and fall on the wall of the opening. Initially, a type of “wall” is then formed until the cross sectional surface-area is then closed.

If the drops are thrown obliquely into the opening, they wet the wall of the opening and thus fill the opening from the inner side.

Alternatively, the two discharge heads can be controlled and/or orientated in such a manner that the drops do not meet in an ideally overlapping manner and consequently fill the opening from two sides.

The above variants can also be used equally well if the opening is filled incompletely.

In a preferred embodiment of the invention, at least one of the two discharge heads can be operated with the continuous and/or drop-on-demand method.

In the case of the continuous ink jet method, the filling material is constantly pumped around and the filling material stream is divided in the discharge head into individual drops by means of an oscillating element. Consequently, up to 100,000 drops per second can be produced. Of the drops produced, up to 30% can be used for the filling operation by these drops being redirected by polarization onto the corresponding surface. The other drops are collected and again supplied in a circuit to the system.

A very rapid application is possible as a result of this method and drop sizes of from 4 pl to 2000 pl can be obtained. A prerequisite is, however, that the filling material can be accordingly polarized.

In contrast, the filling material is released only when it is required in the drop-on-demand method (DOD method).

The application heads are distinguished in this case in accordance with the following technologies: valve technology, thermal ink jet and piezo ink jet.

In the thermal ink jet technology (TIJ), a small electrical heating element, through which the filling material which is located in small channels in the application head is heated until a gas bubble is produced is used in a nozzle. By this bubble being expanded, a drop of the filling material is thrown out of the nozzle. By means of this comparatively slow method, only solvent-containing or water-based filling materials can be processed.

On the other hand, in piezo ink jet systems (PIJ) the drops are produced in that in a nozzle a piezo element made of a piezo-electric ceramic material is provided and voltage is applied thereto. The piezo element thereby expands and the drop is pressed out of the nozzle. The greatest range of usable filling materials can be used with the piezo ink jet method.

The application heads which are relevant here may have up to four rows with 500 nozzles each. In this case, the diameter of these nozzles can be smaller than the diameter of a human hair and each individual nozzle can discharge up to 100,000 ink drops per second, wherein the drop then moves at a speed of up to 10 meters per second.

Embodiments of the invention illustrated in the drawings are explained below. In the drawings:

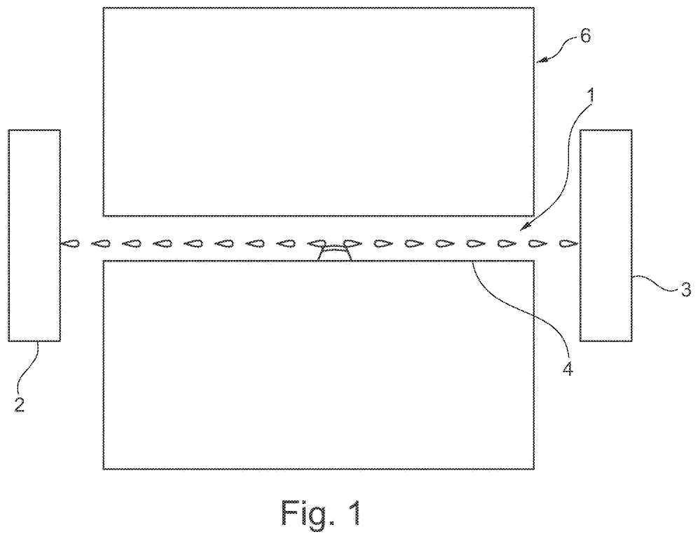

FIG. 1 shows a first method according to the invention,

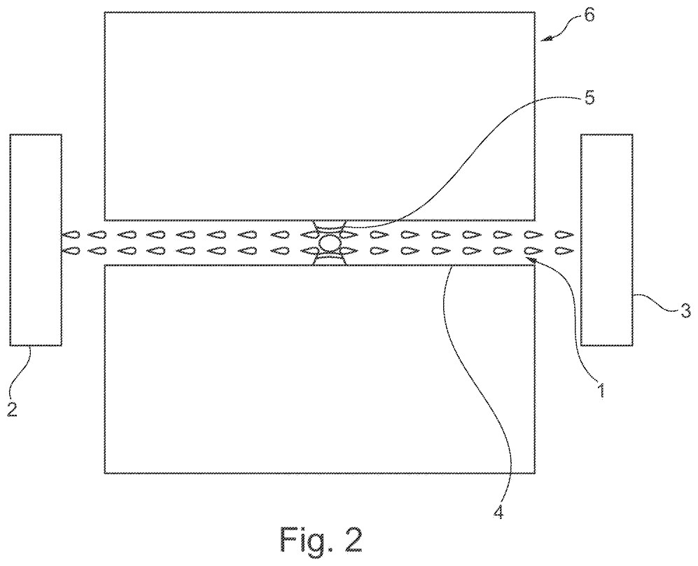

FIG. 2 shows a second method according to the invention and

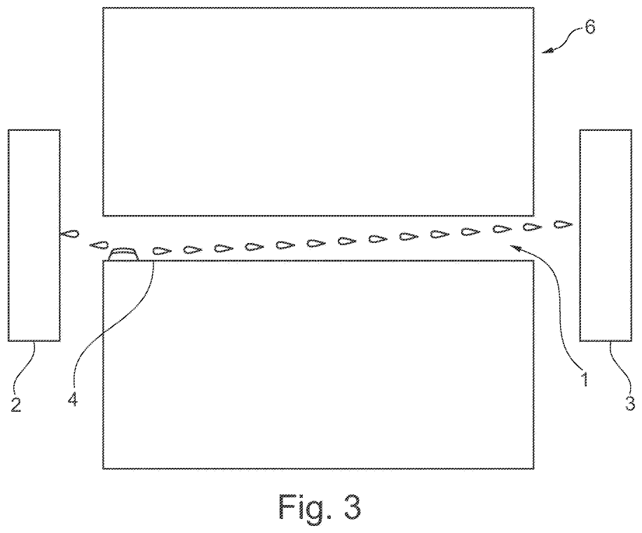

FIG. 3 shows a third method according to the invention.

In all the Figures, corresponding reference numerals are used for identical or similar components.

The Figures illustrate three different methods for closing a channel-shaped opening 1 in a printed-circuit board 6 by means of a liquid, curing filling material.

In this case, the closure of the opening 1 is carried out by means of a digitally controlled application method with two discharge heads 2, 3 which are arranged opposite each other, wherein an ink jet method is used and the discharge heads are in the form of print heads which are arranged opposite each other.

In this case, the discharge heads 2, 3 are controlled in such a manner that the opening 1 is filled with the filling material from both sides by the two ends thereof at the same time. In this case, the filling material is discharged from the two discharge heads 2, 3 taking into consideration the respective performance data of the two discharge heads 2, 3 and the respective spacing of the two discharge heads 2, 3 from the opening so that the discharged quantities of the filling material meet each other inside the opening.

As a result, the filling material which is injected into the opening by the discharge heads 2, 3 does not fly through the opening 1 but instead meets the filling material which comes from the other direction, whereby the filling material sprays away to the side and accumulates on the wall of the opening.

In the method shown in FIG. 1, the two discharge heads 2, 3 are controlled in such a manner that the filling material is discharged from the two discharge heads 2, 3 taking into consideration the respective performance data of the two discharge heads 2, 3 and the respective spacing of the two discharge heads 2, 3 from the opening so that the discharged quantities of the filling material meet each other in the region of the center of the passage length of the opening 1 near a wall 4 of the opening 1. Taking into consideration gravitational force, this may preferably—as shown—be the lower wall 4 of the opening 1.

Then, initially an accumulation of filling material which abuts a region of the wall 4 of the opening 1 is formed and gains height until the opening 1 in this region is closed by a type of dividing wall 5. This is particularly advantageous in the case of complete filling because initially a dividing wall 5 which is arranged at the center of the passage length of the opening 1 and the two blind holes which thereby result can then be further filled by the associated discharge head 2 or 3, respectively.

Alternatively, as shown in FIG. 2, such a dividing wall 5 can also virtually be obtained in one step by discharge heads 2, 3 with a plurality of nozzles. The further filling is also then naturally less time-intensive.

Furthermore, the discharge of the filling material by the discharge heads 2, 3 can also be carried out as shown in FIG. 3, wherein the discharged quantities of the filling material meet approximately in the region of one end of the opening 1. Consequently, the opening 1 can be closed at one side in a flush manner, whereas it remains open from the other side and unfilled.

1. A method for at least partially closing a channel-shaped opening (1) with a cross sectional surface area and a passage length and two opposite ends, in particular through-holes or through-platings in printed-circuit boards (6), with a liquid, curable or curing filling material, wherein the closure of the opening (1) is carried out by means of a digitally controlled application method with two discharge heads (2, 3) which are arranged opposite each other, preferably with an ink jet method with two discharge heads (2, 3) which are arranged opposite each other and which are in the form of print heads, wherein the two discharge heads (2, 3) are controlled in such a manner that the opening (1) is filled with the filling material from both sides by the two ends at the same time and the filling material is discharged from the two discharge heads (2, 3) taking into consideration the respective performance data of the two discharge heads (2, 3) and the respective spacing of the two discharge heads (2, 3) from the opening (1) so that the discharged quantities of the filling material meet each other inside the opening (1).

2. The method as claimed in claim 1, wherein the two discharge heads (2, 3) are controlled in such a manner that the filling material is discharged from the two discharge heads (2, 3) taking into consideration the respective performance data of the two discharge heads (2, 3) and the respective spacing of the two discharge heads (2, 3) from the opening (1) so that the discharged quantities of the filling material meet each other at least approximately in the region of the center of the passage length of the opening (1).

3. The method as claimed in claim 1, characterized in that wherein the two discharge heads (2, 3) are controlled in such a manner that the filling material is discharged from the two discharge heads (2, 3) taking into consideration the respective performance data of the two discharge heads (2, 3) and the respective spacing of the two discharge heads (2, 3) from the opening (1) so that the discharged quantities of the filling material meet each other at least approximately in the region of the center of the cross sectional surface-area of the opening (1).

4. The method as claimed in claim 1, characterized in that wherein the two discharge heads (2, 3) are controlled in such a manner that the filling material is discharged by the two discharge heads (2, 3) taking into consideration the respective performance data of the two discharge heads (2, 3) and the respective spacing of the two discharge heads (2, 3) from the opening so that the cross sectional surface-area of the opening (1) is completely closed.

5. The method as claimed in claim 1, characterized in that wherein the two discharge heads (2, 3) are controlled in such a manner that the filling material is discharged from the two discharge heads (2, 3) taking into consideration the respective performance data of the two discharge heads (2, 3) and the respective spacing of the two discharge heads (2, 3) from the opening (1) so that the opening (1) is completely closed.

6. The method as claimed in claim 1, wherein the filling material is a melt adhesive.

7. The method as claimed in claim 1, wherein the filling material is a UV-curable and/or electron-beam-curable and/or thermally curable ink.

8. The method as claimed in claim 1, wherein the filling material is free from solvents or contains at least one solvent.

9. The method as claimed in claim 1, wherein the filling material is free from particles or filled with particles.

10. The method as claimed in the preceding claim 9,
wherein at least some particles, preferably all the particles, are in the nano-scale size range.

11. The method as claimed in claim 9, wherein at least some particles, preferably all the particles, are thermally conductive.

12. The method as claimed in claim 9, wherein at least some particles, preferably all the particles, are electrically conductive or dielectric.

13. The method as claimed in claim 9, wherein at least some particles, preferably all the particles, are magnetic.

14. The method as claimed in claim 1, wherein the two discharge heads (2, 3) are orientated in such a manner that the trajectory of the filling material which is discharged therefrom is orientated vertically or is redirected only slightly from the perpendicular or is orientated horizontally or is redirected only slightly from the horizontal.

15. The method as claimed in claim 1, wherein at least one of the two discharge heads is operated with the continuous and/or drop-on-demand method.

16. The method as claimed in claim 2, wherein the two discharge heads (2, 3) are controlled in such a manner that the filling material is discharged from the two discharge heads (2, 3) taking into consideration the respective performance data of the two discharge heads (2, 3) and the respective spacing of the two discharge heads (2, 3) from the opening (1) so that the discharged quantities of the filling material meet each other at least approximately in the region of the center of the cross sectional surface-area of the opening (1).

17. The method as claimed in claim 2, wherein the two discharge heads (2, 3) are controlled in such a manner that the filling material is discharged by the two discharge heads (2, 3) taking into consideration the respective performance data of the two discharge heads (2, 3) and the respective spacing of the two discharge heads (2, 3) from the opening so that the cross sectional surface-area of the opening (1) is completely closed.

18. The method as claimed in claim 3, wherein the two discharge heads (2, 3) are controlled in such a manner that the filling material is discharged by the two discharge heads (2, 3) taking into consideration the respective performance data of the two discharge heads (2, 3) and the respective spacing of the two discharge heads (2, 3) from the opening so that the cross sectional surface-area of the opening (1) is completely closed.
